(19) United States
(12) Patent Application Publication
(10) Pub. No.: US 2008/0173904 A1
(43) Pub. Date: Jul. 24, 2008

(54) CMOS image sensors with a bonding pad and methods of forming the same

(75) Inventors: Ming-Chyi Liu, Hsinchu (TW); Shih-Chi Fu, Taipei (TW); Yuan-Hung Liu, Hsinchu (TW); Wei-Chih Chen, Hsinchu (TW); Chi-Hsin Lo, Hsinchu (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO., LTD., Hsin-Chu (TW)

(21) Appl. No.: 11/655,856

(22) Filed: Jan. 22, 2007

(51) Int. Cl. H01L 27/148

(52) U.S. Cl. 257/233; 438/70; 257/E27.15

(57) ABSTRACT

A CMOS image sensor with a bonding pad comprises a semiconductor substrate having a pixel region and a circuit region; a passivation layer having an opening over the semiconductor substrate; and a bonding pad in circuit region, the bonding pad without extending to an upper surface of the passivation layer.

### BACKGROUND OF THE INVENTION

1. Field of the Invention

The invention relates to semiconductor fabrication, and more particularly to complementary metal-oxide-semiconductor (CMOS) image sensors with a bonding pad and methods of forming the same.

2. Description of the Related Art

Image sensors are widely used in digital still cameras, cellular phones, security cameras, medical, automobile, and other applications. The technology used to manufacture image sensors, and in particular CMOS image sensors, has continued to advance at a rapid pace. For example, the demands of higher resolution and lower power consumption have encouraged further miniaturization and integration of image sensors.

US patent publication no. 2006/0148123 discloses a method for fabricating a CMOS image sensor, in which a metal pad is formed on a pad region of a semiconductor substrate having an active region and the pad region. A device passivation layer is formed subsequent to formation of the metal pad.

U.S. Pat. No. 6,348,361 discloses a CMOS image sensor having enhanced photosensitivity and method for fabricating the same. The method comprises the steps of providing a substrate including photosensitive elements and metal wire; forming a first protecting film for protecting the elements over the substrate, covering the metal wire; forming a flattened spin-on-glass film on the first protecting film; forming a second protecting film for protecting the elements on the spin-on-glass film; forming color filter patterns on the second protecting film ; forming a photoresist film for flattening on the color filter patterns and the second protecting film and forming microlenses on the photoresist film. By using the flattened SOG film and a photoresist for flattening and pad opening, the invention provides uniform color filter thickness for corresponding to each unit pixel. The wire-bonding pad is devoid of residual color filter materials and the figure of the microlenses is uniform.

There are, however, still some problems regarding the optical properties of a CMOS image sensor and scattering defects during fabrication of the planarization layer caused by a high topography surface.

### BRIEF SUMMARY OF THE INVENTION

Therefore, there is a need to develop an improved CMOS image sensor with a bonding pad and method of forming the same to eliminate the aforementioned problems.

A method of forming a CMOS image sensor with a bonding pad is provided. A semiconductor substrate having a pixel region and a circuit region is provided. A passivation layer having an opening is formed overlying the semiconductor substrate. A metal layer is conformally formed on the passivation layer leaving a recess at the opening of the metal layer. The metal layer is selectively removed to form a bonding pad without extending to an upper surface of the passivation layer.

A CMOS image sensor with a bonding pad comprises a semiconductor substrate having a pixel region and a circuit region; a passivation layer having an opening over the semiconductor substrate; and a bonding pad in the circuit region, the bonding pad without extending to an upper surface of the passivation layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is cross section of a CMOS image sensor with a bonding pad according to a comparative example;

FIG. 2a to FIG. 2g are schematic diagrams showing an embodiment of a method of forming a CMOS image sensor with a bonding pad;

FIG. 3a to FIG. 3g are schematic diagrams showing another embodiment of a method of forming a CMOS image sensor with a bonding pad;

FIG. 4a to FIG. 4f are schematic diagrams showing yet another embodiment of a method of forming a CMOS image sensor with a bonding pad; and

FIG. 5a to FIG. 5g are schematic diagrams showing still another embodiment of a method of forming a CMOS image sensor with a bonding pad.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

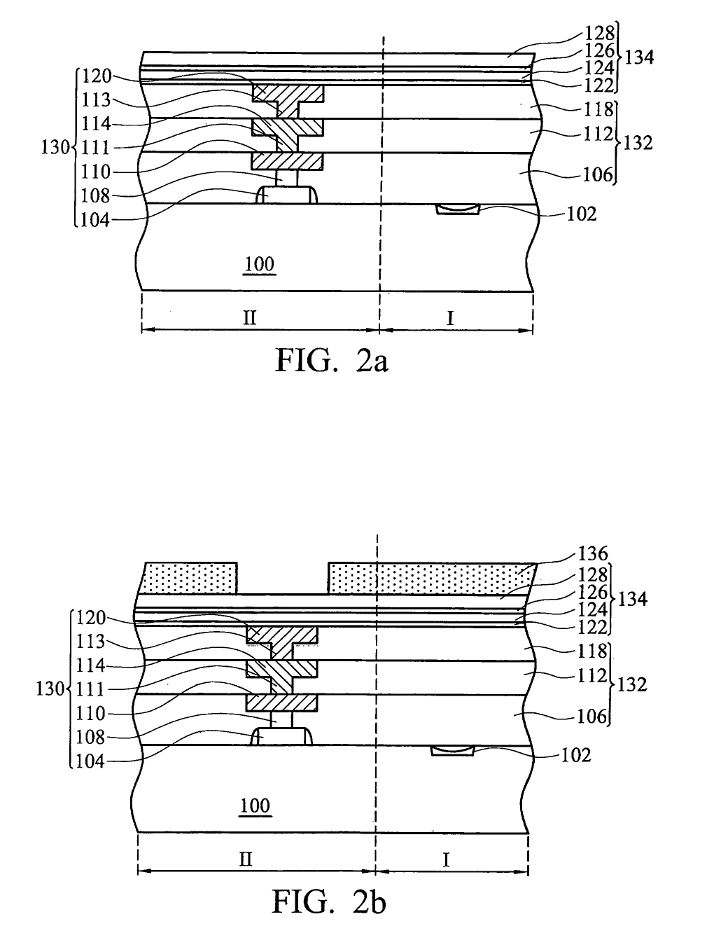

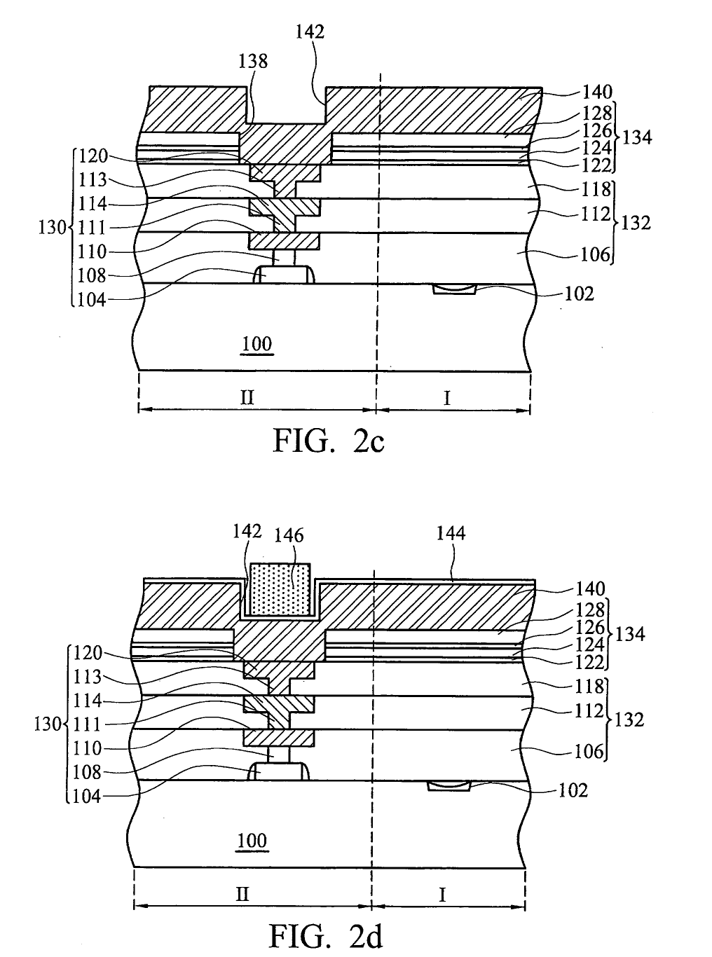

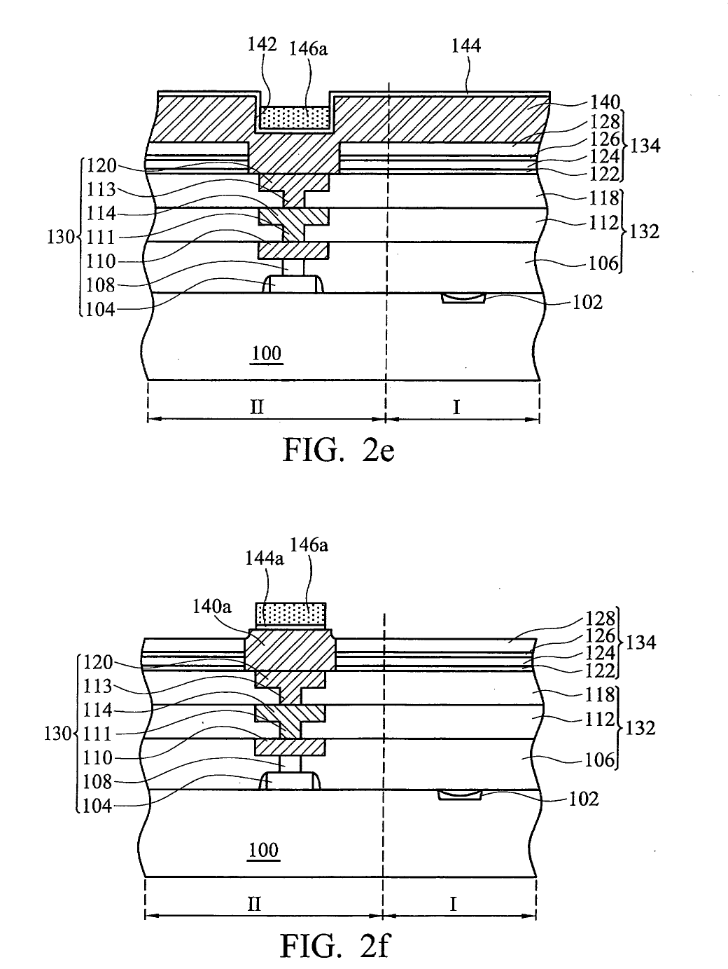

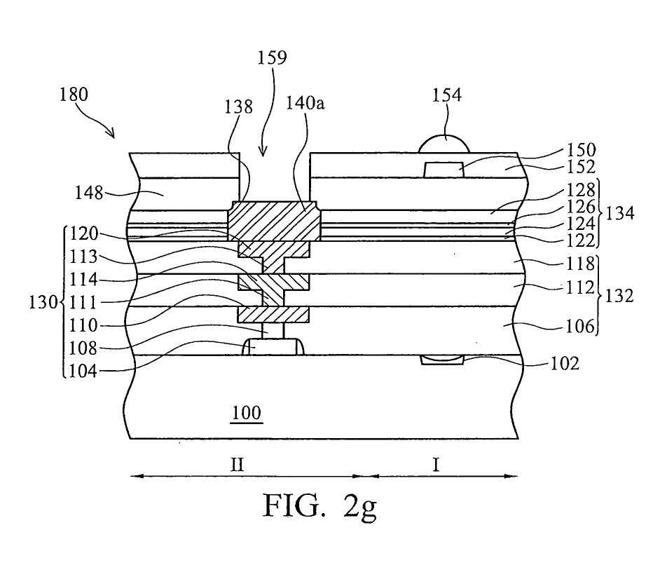

FIG. 2a to FIG. 2g are schematic diagrams showing an embodiment of a method of forming a CMOS image sensor with a bonding pad. As shown in FIG. 2a, a semiconductor substrate 100 having a pixel region I and a circuit region II is provided. The semiconductor substrate 100 may comprise silicon with p-type dopants such P or As. A photodiode 102 is formed in the semiconductor substrate 100 by implanting n-type and/or p-type dopants such as B therein. A variety of semiconductor elements 104 such as n-type metal-oxide-semiconductor (MOS) transistors or/and p-type transistors are formed on the semiconductor substrate 100 in circuit region II. A multi-layer interconnect 130 with a top metal layer 120 inlaid an inter-metal dielectric layer 132 is formed on the semiconductor substrate 100 in circuit region II.

That is, a first dielectric layer 106 is formed on the semiconductor substrate 100 by depositing a low k dielectric material (having a k value less than 3.0) by chemical vapor deposition (CVD) such as low pressure chemical vapor deposition (LPCVD), plasma enhanced chemical vapor deposition (PECVD), high density plasma chemical vapor deposition (HDPCVD), or atomic layer chemical vapor deposition (ALCVD) or spin coating. A wide variety of low-k materials may be employed in accordance with embodiments of the invention, for example, spin-on inorganic dielectrics, spin-on organic dielectrics, porous dielectric materials, organic polymer or organic silica glass. For example, SiLK (manufactured by The Dow Chemical Co. in the U.S.A., k=2.7) or FLARE of a polyallyl ether (PAE) series material (manufactured by Honeywell Electronic Materials Co., k=2.8), Black Diamond (manufactured by Applied Materials Inc. in the U.S.A., k=3.0˜2.4). FSG (SiOF series material), HSQ (hydrogen silsesquioxane, k=2.8˜3.0), MSQ (methyl silsesquioxane, k=2.5˜2.7), porous HSQ, porous MSQ material or porous organic series material may also be used.

A dual damascene structure with a via hole and a trench is then formed in the first dielectric layer 106 by a series of photolithography and anisotropic etching. Next, a copper layer is plated on the first dielectric layer 106 by electrochemical plating (ECP) or electroless plating. The copper layer is then planarized by chemical mechanical polishing (CMP) to form a first layer metal 110 and a contact via 108 connected to at least one of the semiconductor elements 104. A second dielectric layer 112 is then formed on the first dielectric layer 106 by CVD such as LPCVD, PECVD, HDPCVD or ALCVD or spin coating. The material of the second dielectric layer 112 may be the same or different than that of the first dielectric layer 106. A dual damascene structure is formed in the second dielectric layer 112 using a series of photolithography and anisotropic etching. A copper layer is plated on the second dielectric layer 112 followed by planarization of the copper layer to form a second layer metal 114 connected to the first layer metal 110 through the contact via 111. A third dielectric layer 118 is subsequently formed on the second dielectric layer 112 by depositing a low k dielectric material (having a k value less than 3.0) by chemical vapor deposition (CVD) or spin coating. A dual damascene structure is formed in third dielectric layer 118 using a series of photolithography and anisotropic etching. A copper layer is plated on the third dielectric layer 118 followed by planarization of the copper layer to form the top metal layer 120 connected to the second metal 114 through the contact via 113. Therefore, the multi-layer interconnect 130 comprising contact via 108, the first layer metal 110, contact via 111, second layer metal 114, contact via 113, and the top metal layer 120 is inlaid in the inter-metal dielectric layer 132 including the first dielectric layer 106, the second dielectric layer 112 and the third dielectric layer 118.

A passivation layer 134 including a first silicon nitride layer 122, a first oxide layer 124, a second silicon nitride layer 126 and a second silicon oxide layer 128 is formed on the inter-metal dielectric layer 132 by CVD. The passivation layer 134 may protect the circuit on the semiconductor substrate 100 from moisture and contamination. Alternately, the passivation layer 134 may comprise an organic material such as polyimide. The passivation layer 134 may also be a single-layered or a double-layered structure.

As shown in FIG. 2b and FIG. 2c, a photoresist pattern 136 is formed on the passivation layer 134 by photolithography including photoresist spin coating, soft baking, exposing, developing, and hard baking. The passivation layer 134 is anisotropically etched until the surfaces of the top metal layer 120 and the third dielectric layer 118 are exposed while the photoresist pattern 136 is used as an etch mask. The profile of the photoresist pattern 136 is thus transferred to the passivation layer 134 thus creating an opening 138 exposing the top metal layer 120. The opening 138 has dimensions of about 50 to 150 μm. The etching gas for the passivation layer 134 may comprise fluorine-containing gas such as CF₄, CHF₃, or C₄F₈. A metal layer 140 is conformally formed on the passivation layer 134 and the top metal layer 120 by physical vapor deposition (PVD) or sputtering using a target including aluminum or aluminum-copper alloy, thus, a recess 142 in the metal layer 140 aligned with opening 138 is formed.

Referring to FIG. 2d, an anti-reflective layer 144 such as a silicon oxynitride layer is optionally formed on the metal layer 140 followed by forming a photoresist pattern 146 smaller than the recess 142 so as to leave a space between the photoresist pattern 146 and the metal layer 140 or anti-reflective layer 144. The photoresist pattern 146 may be slightly higher than the upper surface of the anti-reflective layer 144 and formed by photolithography. Alternately, the photoresist pattern 146 may have substantially the same dimensions as the recess 142.

As shown in FIG. 2e, the photoresist pattern 146 is heated to form a reflown photoresist 146a within the recess 142 and on the anti-reflective layer 144 at about 150 A to 250 A. Referring now to FIG. 2f, the anti-reflective layer 144 and the metal layer 140 are anisotropically etched to leave a bonding pad 140a and an anti-reflective layer 144a. The etching gas for the metal layer 140 may comprise chlorine-containing gas such as Cl₂ or BCl₃. In this step, the reflown photoresist 146a serves as an etch mask. It is noted that the bonding pad 140a does not extend to the upper surface of the passivation layer 134 and is relatively less thick. In this embodiment, the upper surface of the bonding pad 140a may be slightly higher than that of the passivation layer 134 and the height difference between the bonding pad 140a and the passivation layer 134 may be less than 3,000 Å.

As shown in FIG. 2g, the reflown photoresist 146a and the anti-reflective layer 144a are stripped or etched to expose the bonding pad 140a. A first planarization layer 148 is formed on the passivation layer 134 and the bonding pad 140a. The first planarization layer 148 having a thickness less than about 3000 Å may comprise spin on glass (SOG) formed by spin coating. A color filter 150 is formed on the first planarization layer 148 in the pixel region I followed by forming a second planarization layer 152 on the first planarization layer 148 and color filter 150. The second planarization layer 152 may comprise spin on glass (SOG) formed by spin coating. A microlens 154 is then formed on the second planarization layer 152, wherein the microlens 154 is substantially aligned with the color filter 150. In other embodiments, an additional passivation layer (not shown) is formed on the bonding pad 140a to further protect the bonding pad 140a before forming the first planarization layer 148.

FIG. 2g shows a CMOS image sensor 180 comprising a semiconductor substrate 100 having a pixel region I and a circuit region II, a passivation layer 134 having an opening 138 over the semiconductor substrate 100 and a bonding pad 140a in circuit region II, the bonding pad 140a without extending to an upper surface of the passivation layer 134.

The CMOS image sensor 180 may further comprise a first planarization layer 148 on the passivation layer 134 and the bonding pad 140a, a color filter 150 on the first planarization layer 134 in the pixel region, a second planarization layer 152 on the first planarization layer 148 and color filter 150. The CMOS image sensor 180 may further a microlens 154 on the second planarization layer 152, wherein the microlens 154 is substantially aligned with the color filter 150.

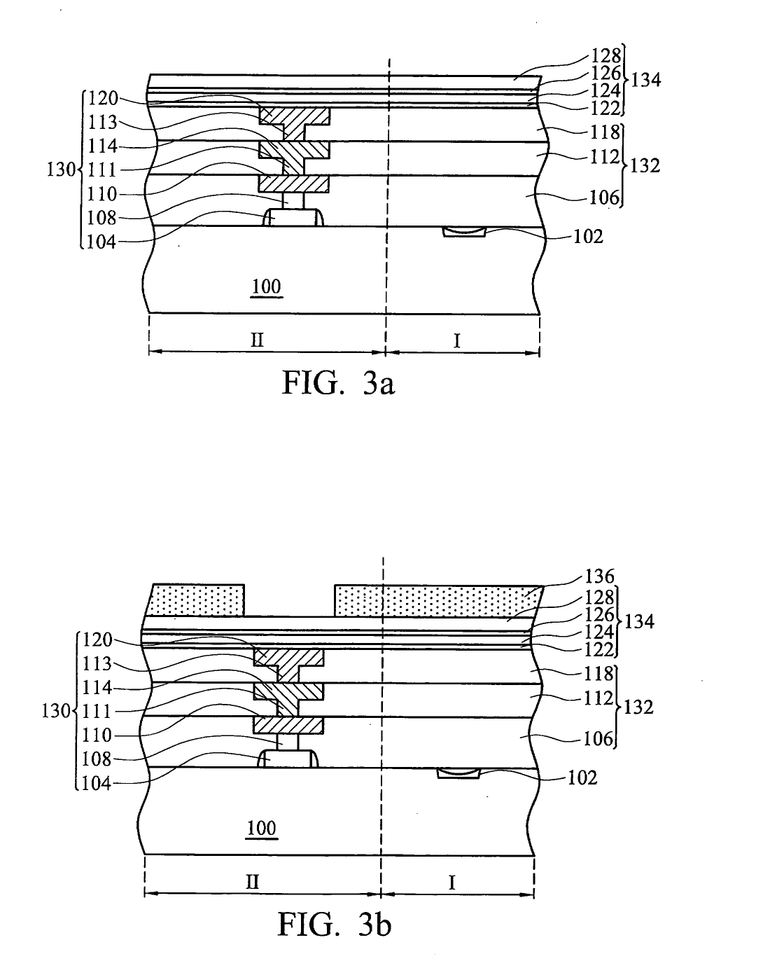

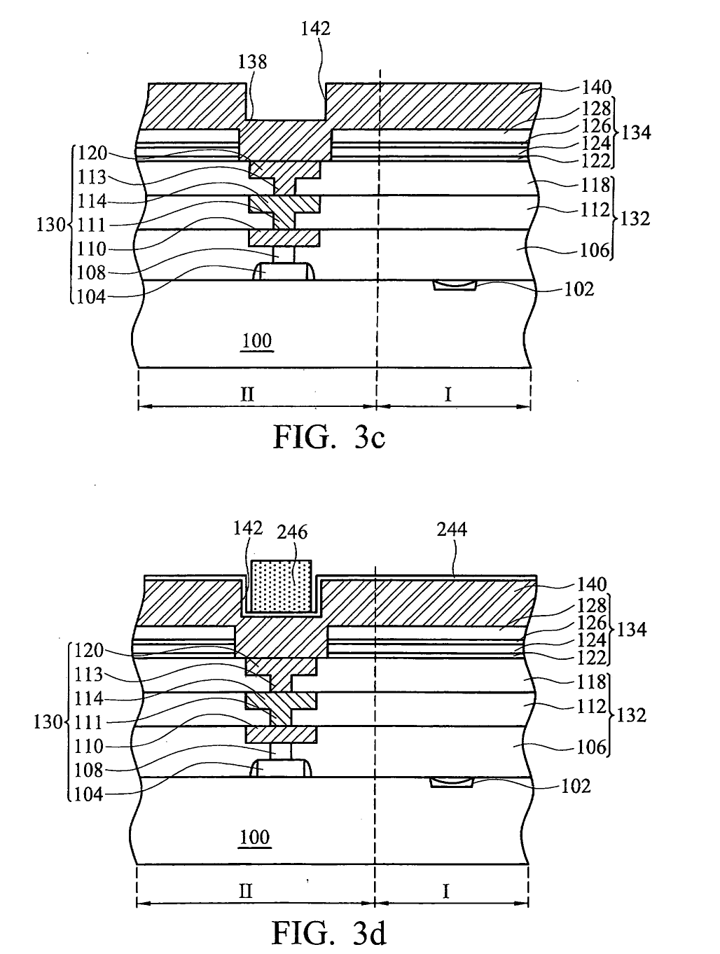

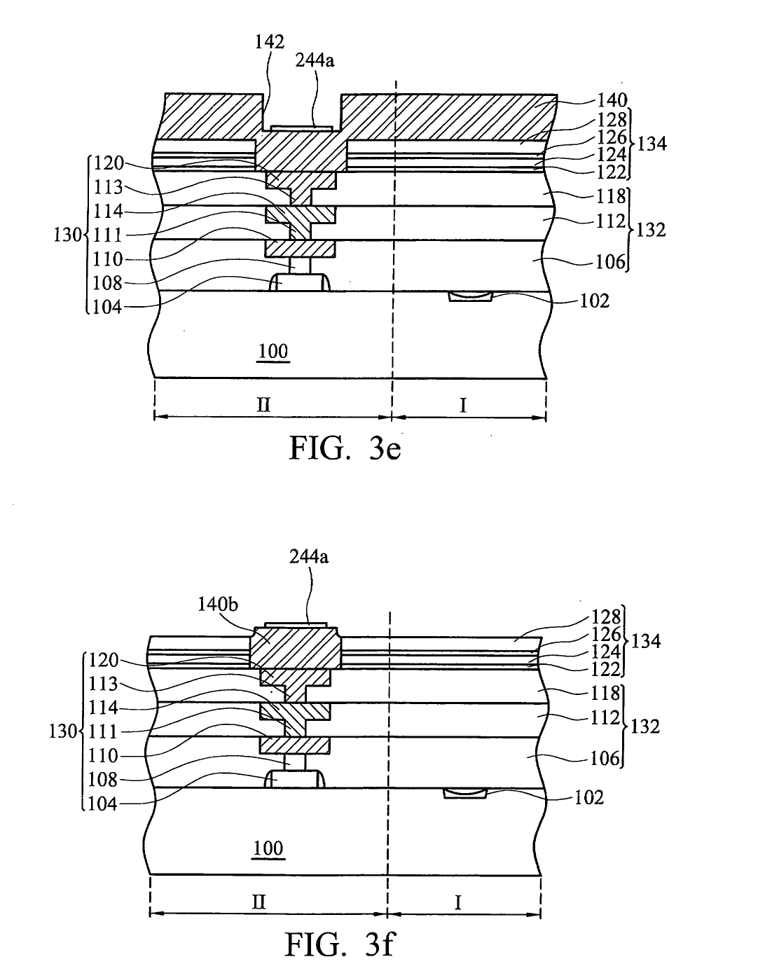

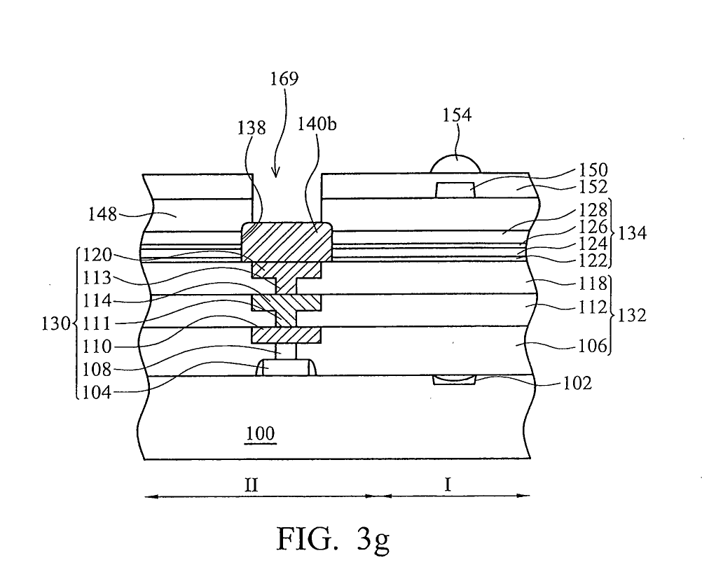

FIG. 3a to FIG. 3g are schematic diagrams showing another embodiment of a method for fabricating a CMOS image sensor with a bonding pad. The exemplary method as shown in FIG. 3a to FIG. 3g is substantially similar to that as shown in FIG. 2a to FIG. 2g with the exception of the process for forming a bonding pad as shown in FIG. 3d to FIG. 3f. The same steps in this method are not described again for brevity. As shown in FIG. 3d, an anti-reflective layer 244 such as a silicon oxynitride layer having a thickness of about 100 Å to 500 Å is formed on the metal layer 140 by CVD such as LPCVD, PECVD, HDPCVD or ALCVD. Alternately, other inorganic materials such as silicon nitride or silicon carbide can be used as the anti-reflective layer 244. A photoresist pattern 246 smaller than the recess 142 is formed over the anti-reflective layer 244 by photolithography so that there is a space between the photoresist pattern 246 and the anti-reflective layer 244.

Referring now to FIG. 3f and FIG. 3g, the anti-reflective layer 244 is partially removed to leave a hard mask 244a and expose the metal layer 140 using the photoresist pattern 246 as an etch mask followed by stripping the photoresist pattern 246 with for example oxygen plasma. The metal layer 140 is planarized to form a bonding pad 140b under the hard mask 244a by chemical mechanical polishing (CMP). In this step, the hard mask 244a serves as a polish hard mask.

As shown in FIG. 3g, the hard mask 244a is removed to expose the bonding pad 140b. A first planarization layer 148 is formed on the passivation layer 134 and the bonding pad 140b. The first planarization layer 148 having a thickness less than about 3000 Å may comprise spin on glass (SOG) formed by spin coating. A color filter 150 is formed on the first planarization layer 148 in the pixel region I followed by forming a second planarization layer 152 on the first planarization layer 148 and color filter 150. The second planarization layer 152 may comprise spin on glass (SOG) formed by spin coating. A microlens 154 is then formed on the second planarization layer 152, wherein the microlens 154 is substantially aligned with the color filter 150.

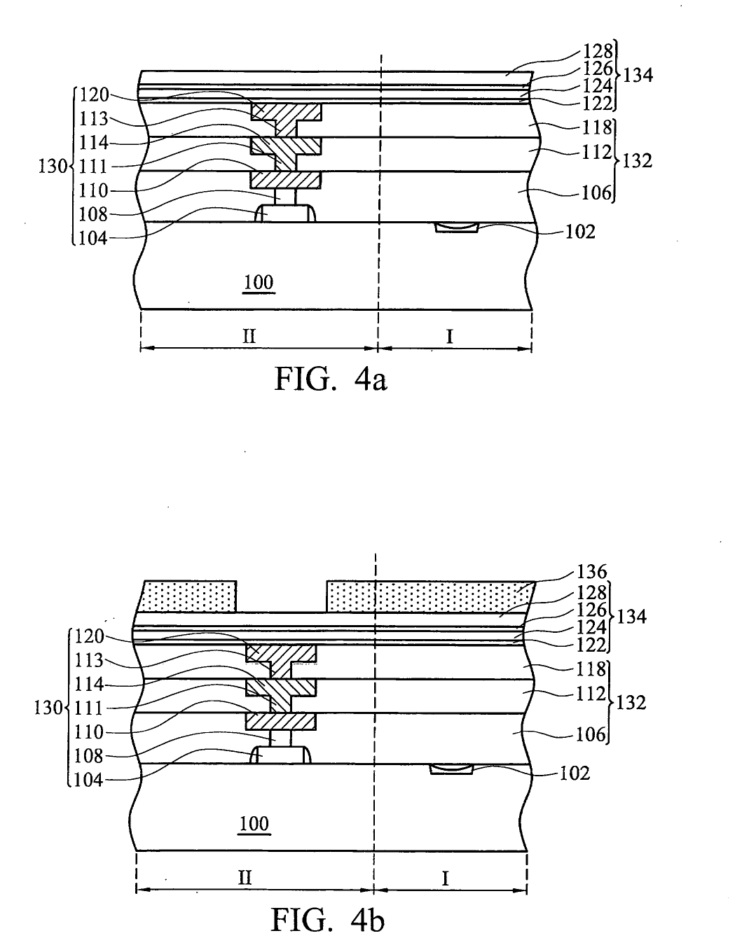

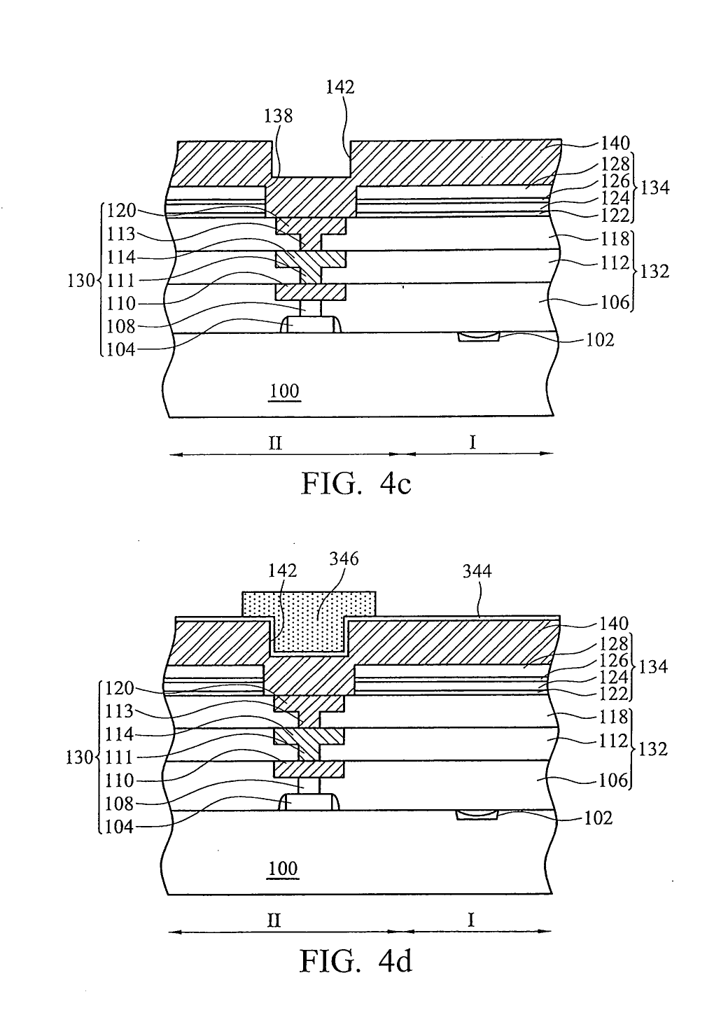

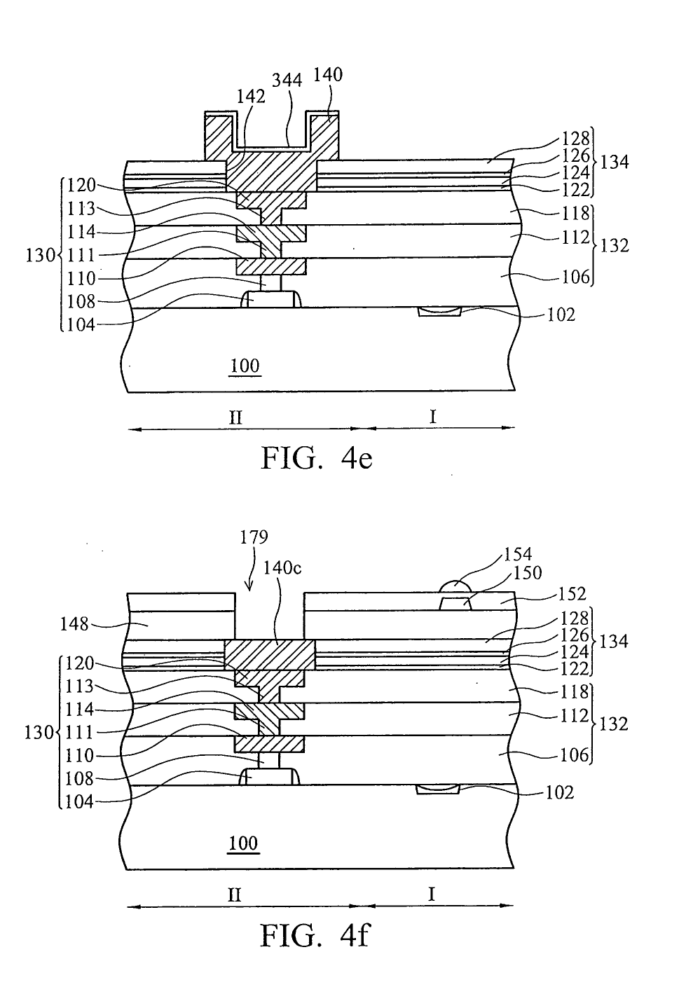

FIG. 4a to FIG. 4f are schematic diagrams showing yet another embodiment of a method for fabricating a CMOS image sensor with a bonding pad. The exemplary method as shown in FIG. 4a to FIG. 4f is substantially similar to that shown in FIG. 2a to FIG. 2g with the exception of the process for forming a bonding pad as shown in FIG. 4d to FIG. 4f. Description of steps in this embodiment that are identical to steps in other embodiments is omitted for brevity. As shown in FIG. 4d, an anti-reflective layer 344 is optionally formed on the metal layer 140. Then, a photoresist pattern 346 is formed over the recess 142 and the anti-reflective layer 344 by photolithography. It is noted that the photoresist pattern 346 is larger than the recess 142. As shown in FIG. 4e, the anti-reflective layer 344 and the metal layer 140 are partially etched using the photoresist pattern 346 as the etch mask followed by removal of the photoresist pattern 346. As shown in FIG. 4f, the metal layer 140 and the anti-reflective layer 344 are planarized by chemical mechanical polishing (CMP) to form a bonding pad 140c substantially coplanar with the passivation layer 134. The upper surface of the bonding pad 140c may be slightly lower than that of the passivation layer 134. A first planarization layer 148 is formed on the passivation layer 134 and the bonding pad 140c. The first planarization layer 148 having a thickness less than about 3000 Å may comprise spin on glass (SOG) formed by spin coating. A color filter 150 is formed on the first planarization layer 148 in the pixel region I followed by forming a second planarization layer 152 on the first planarization layer 148 and color filter 150. The second planarization layer 152 may comprise spin on glass (SOG) formed by spin coating. A microlens 154 is then formed on the second planarization layer 152, wherein the microlens 154 is substantially aligned with the color filter 150.

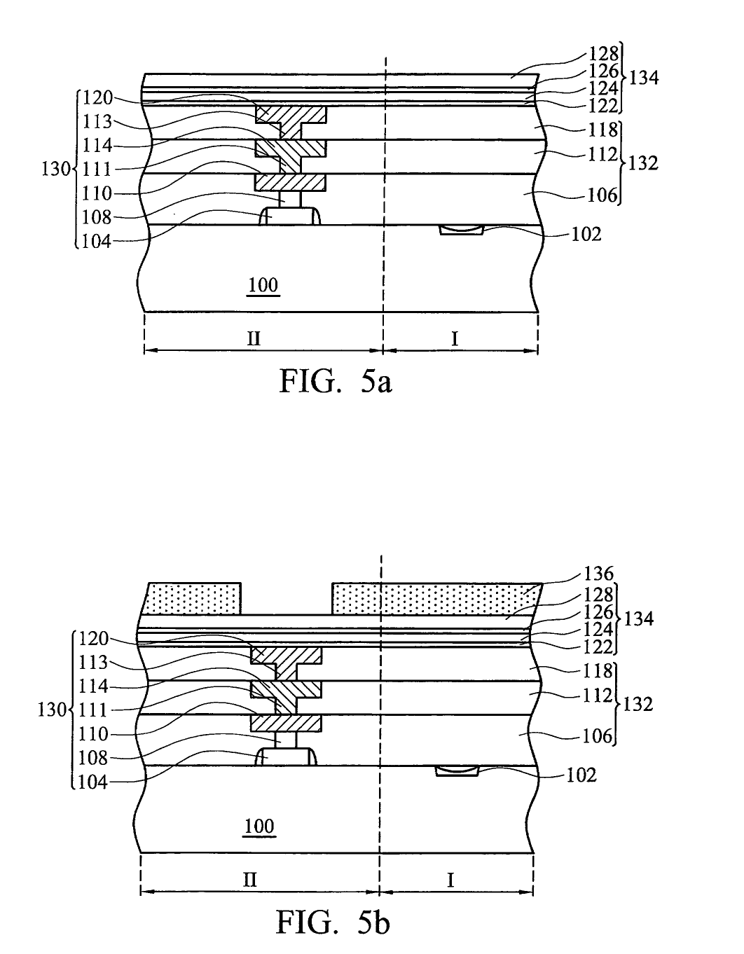

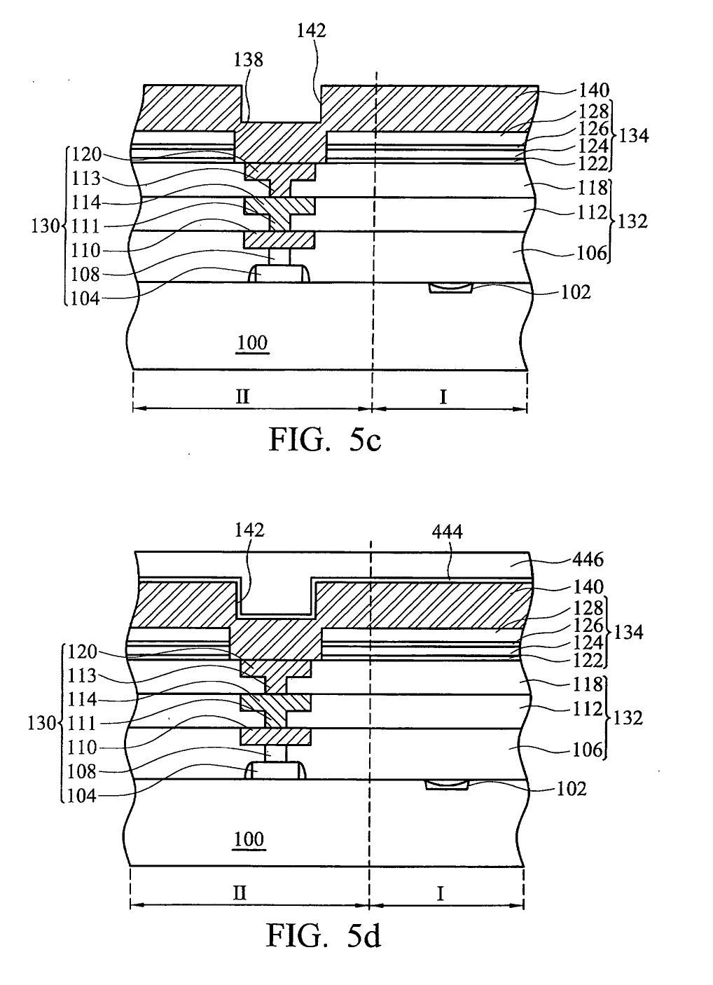

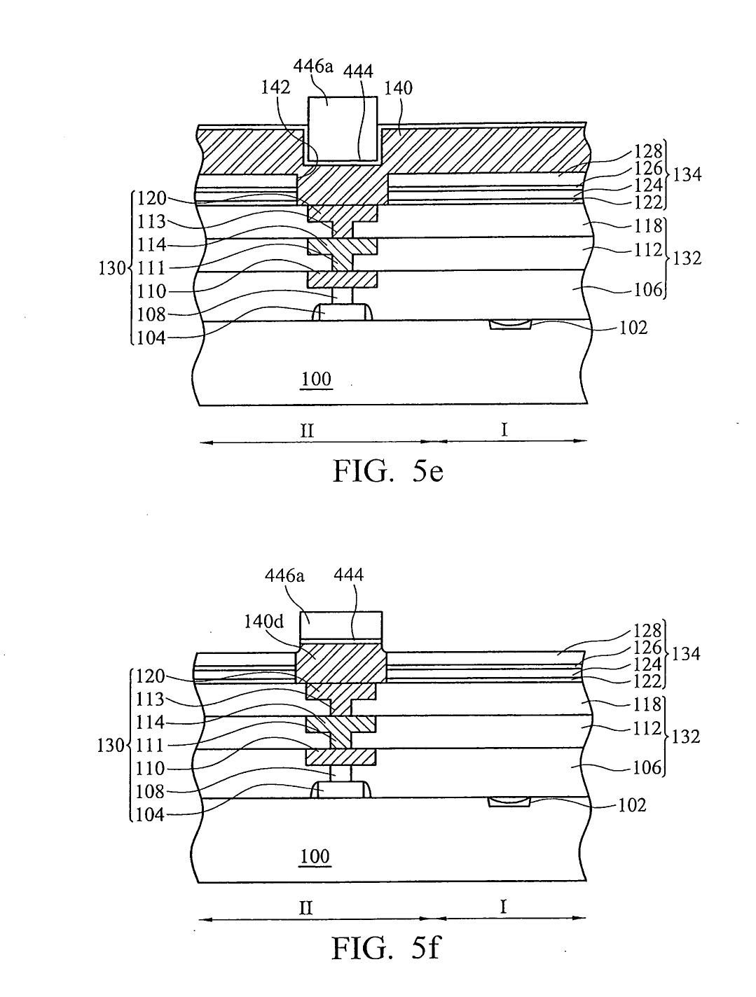

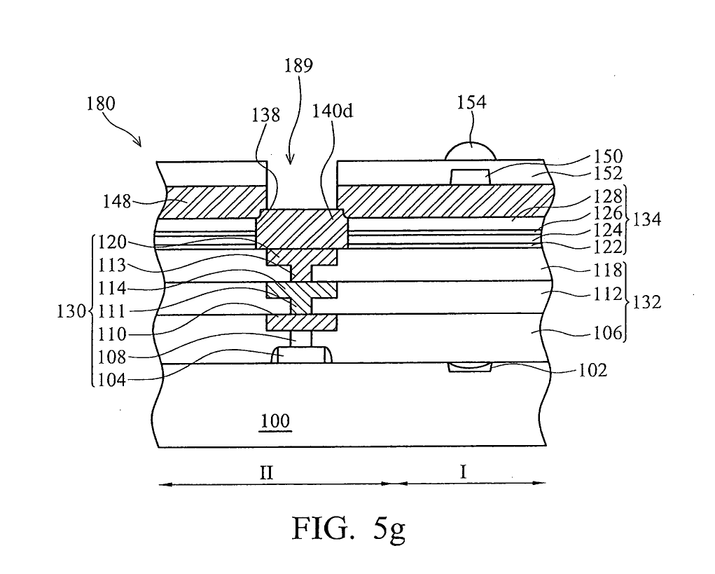

FIG. 5a to FIG. 5g are schematic diagrams showing still another embodiment of a method of forming a CMOS image sensor with a bonding pad. The exemplary method as shown in FIG. 5a to FIG. 5g is substantially similar to that as shown in FIG. 2a to FIG. 2g except the process to form a bonding pad as shown in FIG. 5d to FIG. 5f. As shown in FIG. 5d, an anti-reflective layer 444 is optionally formed on the metal layer 140 followed by forming a material layer 446 over the metal layer 140 and filling the recess 142. The material layer 446 may comprise spin on glass or bottom anti-reflective layer (BARL) formed by spin coating. The material layer 446 is etched back by e-beam to leave a remaining material 446a within the recess 142 as shown in FIG. 5e.

Referring now to FIG. 5f and FIG. 5g, the anti-reflective layer 444 and the metal layer 140 are partially removed using the remaining material 446a as an etch mask to form a bonding pad 140d. The remaining material 446a and anti-reflective layer 444 are removed to expose the bonding pad 140d. A first planarization layer 148 is formed on the passivation layer 134 and the bonding pad 140c. The first planarization layer 148 having a thickness less than about 3000 Å may comprise spin on glass (SOG) formed by spin coating. A color filter 150 is formed on the first planarization layer 148 in the pixel region I followed by forming a second planarization layer 152 on the first planarization layer 148 and color filter 150. The second planarization layer 152 may comprise spin on glass (SOG) formed by spin coating. A microlens 154 is then formed on the second planarization layer 152, wherein the microlens 154 is substantially aligned with the color filter 150.

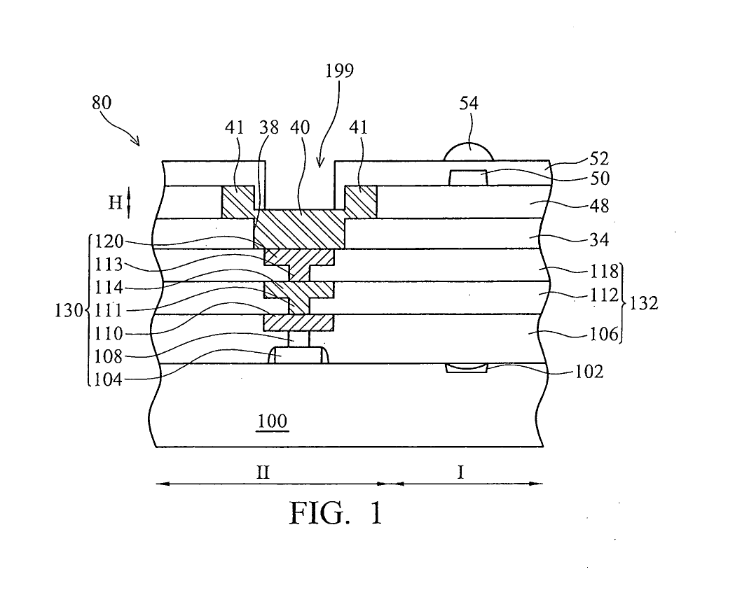

Referring now to FIG. 1, a CMOS image sensor 80 comprises a semiconductor substrate 100 having a pixel region I and a circuit region II, a passivation layer 34 having an opening 38 over the semiconductor substrate 100 and a bonding pad 40 in circuit region II. It is noted that the bonding pad 40 is formed by anisotropic etching with a photoresist pattern (not shown) directly defined by a well-known photolithography so that the bonding pad 40 has elevated edges 41 resulting in relatively higher topography surface. In other words, the height difference H between the bonding pad 40 and the passivation layer 34 is about 3000 Å to 15000 Å.

The CMOS image sensor 80 may further comprise a comparatively thicker first planarization layer 48 on the passivation layer 34 and the bonding pad 40, a color filter 50 on the first planarization layer 34 in the pixel region I, a second planarization layer 52 on the first planarization layer 48 and color filter 50 and a microlens 54 on the second planarization layer 52, wherein the microlens 54 is substantially aligned with the color filter 50. It is noted that the first planarization 148 is relatively thicker thus the CMOS image sensor 80 may have poor optical properties. Scattering defects may also occur on the semiconductor substrate or wafer during formation of the spin-coated first planarization layer because of relatively higher topography surface.

According to the exemplary methods of forming a CMOS image sensor with a bonding pad, the height difference between the bonding pad and the passivation layer can be significantly reduced. The planarization layer on the bonding pad can be spin-coated on the semiconductor substrate having comparatively low topography surface. The scattering defects on semiconductor substrate or wafer caused by spin coating may be eliminated. Moreover, the thickness of the planarization layer may be reduced thus improving the optical properties the CMOS image sensor.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method of forming a CMOS image sensor with a bonding pad, comprising:
providing a semiconductor substrate having a pixel region and a circuit region;
forming a passivation layer having an opening overlying the semiconductor substrate;
conformally forming a metal layer on the passivation layer so that the metal layer has a recess at the opening; and
selectively removing the metal layer to form a bonding pad without extending to an upper surface of the passivation layer.

2. The method of forming a CMOS image sensor with a bonding pad as claimed in claim 1, further comprising forming a multi-layer interconnect with a top metal layer inlaid in an inter-metal dielectric layer before forming the passivation layer, wherein the opening exposes the top metal.

3. The method of forming a CMOS image sensor with a bonding pad as claimed in claim 2, wherein the multi-layer interconnect comprises copper damascene interconnect.

4. The method of forming a CMOS image sensor with a bonding pad as claimed in claim 1, further comprising:
forming a first planarization layer on the passivation layer and the bonding pad;
forming a color filter on the first planarization layer in the pixel region;
forming a second planarization layer on the first planarization layer and color filter; and
forming a microlens on the second planarization layer, wherein the microlens is substantially aligned with the color filter.

5. The method of forming a CMOS image sensor with a bonding pad as claimed in claim 4, wherein the first and the second planarization layers comprise spin on glass formed by spin coating.

6. The method of forming a CMOS image sensor with a bonding pad as claimed in claim 1, wherein the passivation layer comprises a stacked layer including at least one silicon oxide layer and at least one silicon nitride layer.

7. The method of forming a CMOS image sensor with a bonding pad as claimed in claim 1, wherein the metal layer is performed by forming aluminum or aluminum-copper alloy using physical vapor deposition or sputtering.

8. The method of forming a CMOS image sensor with a bonding pad as claimed in claim 1, wherein forming the bonding pad further comprises:
forming a photoresist pattern smaller than the recess overlying the metal layer;
thermally reflowing the photoresist pattern to form a reflown photoresist within the recess; and
partially removing the metal layer using the reflown photoresist as an etch mask to form a bonding pad.

9. The method of forming a CMOS image sensor with a bonding pad as claimed in claim 8, further comprising forming an anti-reflective layer on the metal layer before forming the photoresist pattern.

10. The method of forming a CMOS image sensor with a bonding pad as claimed in claim 1, wherein forming the bonding pad further comprises:
forming a material layer overlying the metal layer and filling the recess;
etching back the material layer to leave a remaining material within the recess; and
partially removing the metal layer using the remaining material as an etch mask to form a bonding pad.

11. The method of forming a CMOS image sensor with a bonding pad as claimed in claim 10, wherein the material layer comprises spin on glass or bottom anti-reflective formed by spin coating.

12. The method of forming a CMOS image sensor with a bonding pad as claimed in claim 10, wherein etching back the material layer is performed by e-beam.

13. The method of forming a CMOS image sensor with a bonding pad as claimed in claim 10, further comprising forming an anti-reflective layer on the metal layer before forming the material layer.

14. The method of forming a CMOS image sensor with a bonding pad as claimed in claim 1, wherein forming the bonding pad further comprises:
forming an anti-reflective layer on the metal layer;
forming a photoresist pattern smaller than the recess overlying the anti-reflective layer;
partially removing the anti-reflective layer using the photoresist pattern as an etch mask and leave a hard mask;
stripping the photoresist pattern; and
planarizing the metal layer to form a bonding pad under the hard mask.

15. The method of forming a CMOS image sensor with a bonding pad as claimed in claim 14, wherein the anti-reflective layer comprises silicon oxynitride.

16. The method of forming a CMOS image sensor with a bonding pad as claimed in claim 14, wherein planarizing the metal layer is performed by chemical mechanical polishing or etching back.

17. The method of forming a CMOS image sensor with a bonding pad as claimed in claim 1, wherein forming the bonding pad further comprises:
forming a photoresist pattern overlying the recess and the metal layer;
partially removing the metal layer using the photoresist pattern as the etch mask; and
planarizing the metal layer to form a bonding pad.

18. The method of forming a CMOS image sensor with a bonding pad as claimed in claim 17, wherein planarizing the metal layer is performed by chemical mechanical polishing.

19. A CMOS image sensor with a bonding pad, comprising:
a semiconductor substrate having a pixel region and a circuit region;
a passivation layer having an opening over the semiconductor substrate; and
a bonding pad in the circuit region, wherein a surface of the bonding pad is higher than a top surface of the passivation layer and the bonding pad does not cover the top surface of the passivation layer.

20. The CMOS image sensor with a bonding pad as claimed in claim 19, further comprising a multi-layer interconnect with a top metal layer inlaid in an inter-metal dielectric layer between the semiconductor substrate and the passivation layer in the circuit region.

21. The CMOS image sensor with a bonding pad as claimed in claim 20, wherein the multi-layer interconnect comprises copper damascene interconnect.

22. The CMOS image sensor with a bonding pad as claimed in claim 19, further comprising:
a first planarization layer on the passivation layer and the bonding pad;
a color filter on the first planarization layer in the pixel region;
a second planarization layer on the first planarization layer and color filter; and
a microlens on the second planarization layer, wherein the microlens is substantially aligned with the color filter.

23. The CMOS image sensor with a bonding pad as claimed in claim 22, wherein the first and second planarization layers comprises spin on glass.

24. (canceled)

25. (canceled)

26. The CMOS image sensor with a bonding pad as claimed in claim 19, wherein the bonding pad is substantially coplanar with the passivation layer.

27. The CMOS image sensor with a bonding pad as claimed in claim 19, further comprises a photodiode in pixel region of the semiconductor substrate.

28. The CMOS image sensor with a bonding pad as claimed in claim 20, wherein the top metal layer comprises aluminum or aluminum-copper alloy.
